(19) United States
(12) Patent Application Publication
(10) Pub. No.: US 2004/0132300 A1
(43) Pub. Date: Jul. 8, 2004

(54) Procedure for activation of substrates for plastic galvanizing

(75) Inventor: Andreas Konigshofen, Koln (DE)

Correspondence Address: SENNIGER POWERS LEAVITT AND ROEDEL, ONE METROPOLITAN SQUARE, 16TH FLOOR, ST LOUIS, MO, 63102, US

(73) Assignee: Enthone Inc.

(21) Appl. No.: 10/739,842

(22) Filed: Dec. 18, 2003

(30) Foreign Application Priority Data
Dec. 18, 2002 (DE) 102 59 187.3

(51) Int. Cl. B05D 3/10; H01L 21/302; H01L 21/461

(52) U.S. Cl. 438/689

(57) ABSTRACT

This invention concerns a method for metal plating plastic substrates, where the plastic surfaces are etched, activated, rinsed, optionally treated with an accelerator, and metal plated by chemical reductive or electrolytic means.

In order to provide metal plating of plastic substrates that is simple, cheap, and rapid, yet produce metal platings that are functionally reliable and reproducible, the etching and activation of the plastic substrates in the invention is carried out in a common process step, which takes place in an etch-activation solution containing at least one mineral acid-containing etching agent and an ionic activator.

Moreover, a solution is disclosed that is suitable in particular for use with the process of the invention, which is made available for simultaneous etching and activation of active substrates containing one or more etching agents, an etching-active wetting agent, hydrochloric acid and an activator containing noble metal ions.

### BACKGROUND OF THE INVENTION

The present invention relates generally to metal plating of plastic substrates by etching, activating, rinsing, treating, and metallizing the plastic substrate.

The development of methods for metal plating plastics is today being pushed especially intensively because of the considerably advantageous functional properties that can be achieved therewith, especially when compared to coated metal objects, beyond just the formation of decorative surfaces. The very low weight and easier, cost-effective production of plastics, combined with their uncomplicated processability and extensive design possibilities, have already given them a solid place on the market, especially in the decorative sector or in the field of electronic applications.

With the demand for metal-coated plastics of the most varied kinds, there is also a further increase in the number of metal plating processes and metallizable plastics. A basic prerequisite for electroplating a plastic substrate is that the nonconductive plastic be solidly coated with a conductive layer as a basis for the subsequent metal plating.

With the most current methods, the plastic substrate is first etched in order to roughen or chemically modify the surface, thereby facilitating the absorption of metal seeds. Etching is carried out, for example, by chromium-sulfuric acid etching agents, acid or alkaline permanganate etching agents, or other oxidizing etching agents. Alternatively, the plastic substrate surfaces can be roughened through a plasma treatment. The etched plastic parts are rinsed and subsequently provided with a metal seed coat, or activated. Activation is followed by either a chemically reductive or electroless metal deposition of a conducting layer on the plastic surface, with subsequent electrolytic layer formation, or immediate direct metal plating, in each case according to the activation layer.

The activation can take place by colloidal or ionic catalysis and through the use of metal activators or metal complex activators. The latter form employs sparingly soluble sulfides and polysulfides, where tin, lead, silver, cobalt, manganese and copper are especially suitable as metals. The classical colloidal process, however, includes a number of time-intensive and cost-intensive reducing and rinsing operations.

Recent methods based on metal or metal complex activators do enable a considerably shorter treatment time, but not just any plastic is suitable for permeation and deposition of such metal complexes. In these methods, the loosely held superficial complexes are removed and an uneven or incomplete cross linking of the metal complexes with a cross linking solution results after rinsing or an intermediate dip in solution. This leads disadvantageously to incomplete metal plating of the plastic surface, to tearing, or to peeling, or a combination thereof, of the dry metal plated layer.

In contrast, methods of ionic catalysis offer simplifications over the traditional variations, are insensitive to the entrained chemical of successive baths, and thus are gentle on the environment. However, the methods of ionic catalysis are still not suitable for all plastics.

In particular, plastics like polyacetate, polysulfone, polystyrene, polyphenylene oxide, polypropylene, or polyamide can still not be metallized at all with the described methods, or can be metal plated only at high costs using some specialized process. For example, it is possible to metal plate some of these plastics by targeted matching of the pickling solution for the relevant plastic and through additional cost-intensive process adjustments. Because of the need to adhere to quite specific process conditions, such methods are frequently extremely sensitive to processing problems. Even the smallest changes in the process conditions can result in the plastic surface not being optimally prepared, which results in functionally unreliable and unsatisfactory bonding of the metal layer to the plastic surface such that sufficiently reproducible results still cannot be achieved. In particular, the wrong etching times will disadvantageously change the surface, so that extremely precise controls will be required to keep the reject rate low.

In particular, workpieces of polyamide can be electroplated by the methods known in the prior art only at an unjustifiably high cost, if at all. For instance, until now process steps were often carried out several times in order to produce essentially satisfactory metal layers, where mainly the activation step is carried out several times in succession. However, repeating processing steps, such as the activation step, reduces the yield of effectively coated parts, especially in the case of larger workpieces, to a degree that can only be called unsatisfactory.

Heretofore, etching and activation have been accomplished in independent process steps and in separate process solutions because known etching solutions have been incompatible with known activation solutions. Therefore, there remains a persistent desire to improve the process for metal plating plastic substrates by, for example, combining multiple processing steps.

### SUMMARY OF THE INVENTION

Among the several aspects of the invention is to provide metal plated plastic surfaces of various kinds.

Briefly, therefore, the invention is directed to a method for metal plating a plastic substrate comprising etching and activating the plastic substrate by exposing the substrate to an etch-activation solution comprising a mineral acid-containing etching agent and an ionic activator, and plating metal onto the substrate by chemically reductive metal deposition or electrolytic metal deposition in a plating solution.

The invention is also directed to a method for metal plating a plastic substrate comprising the two stages and their respective solutions listed above as well as an accelerator solution, to which the plastic substrate is exposed before plating the metal onto the substrate.

In another aspect the invention is a solution for simultaneous etching and activation of plastic substrates comprising an etching agent, an etching-active wetting agent, a mineral acid, and an activator containing noble metal ions.

The present invention improves the ability of plastics to be metallized, yielding functionally reliable and reproducible metal coatings that are produced in a simple, cheap, and rapid process. This is accomplished by carrying out both the etching and activation of the process step in a single solution containing at least one mineral acid-containing etching solution and an ionic activator.

Other objects and features will be in part apparent, and in part described hereafter.

### DESCRIPTION OF THE PREFERRED EMBODIMENT

The invention involves the metallization of plastic substrates. More particularly, this invention advantageously results in a considerably simpler and more economical conditioning of plastics in preparation for metal plating, allows a reduction of the number of process steps, and an improvement of the bond strength of the metal plating layer to plastic substrates.

In the conditioning process, etching and activation of a plastic substrate that is to be metal plated is carried out in a single first solution (an etch-activation solution) that contains at least one mineral acid-containing etching solution and an ionic activator. Additionally, the plastic substrate to be metal plated can be metal plated in a manner less susceptible to processing problems and at a reduced cost. Along these lines, the etching agent is advantageously matched to the activation solution in order to use this as a first solution for conditioning the plastic substrates. This etch-activation solution advantageously conflates two process steps into one process step because of its optimized composition. The etch-activation solution contains at least one etching agent, an etching-active wetting agent, a mineral acid such as hydrochloric acid, sulfuric acid, nitric acid, etc., and an activator containing noble metal ions, preferably palladium ions. In general, the etching agent is matched to the activator and activation solution with regard to solubility and pH-value.

Surprisingly, the invention is effective not only for large-surface-area workpieces, but also geometrically complex workpieces. In addition, the invention produces polyamide plastic substrates that are conditioned in the etch-activation solution so as to produce a surface structure with a distinct roughness and with a large number of voids. Such a surface facilitates optimum or complete seeding with activator molecules, which is necessary for, e.g., the direct metal plating process.

Just as surprisingly, the etch-activation solution of the invention, through the simultaneous roughening and activation of the plastic surface with a cross linking agent and an ionic activator, promotes the incorporation of the activator molecules into the generated voids when compared to the traditional process where the activation step takes place at the end of etching. Accordingly, the activator seeds introduced during the conditioning step advantageously penetrate considerably deeper into the voids produced in the plastic. In turn, this favors a uniformly deeper penetration of the metal layer into the plastic in a subsequent metal plating process, yielding considerably better adhesion between the metal layer and the plastic than with traditional process methods.

In one embodiment of the invention, the treatment of plastic substrates with the etch-activation solution takes place at a temperature between about 20° C. and 90° C., preferably between about 30° C. and 35° C. Lower processing temperatures such as these permit for reduced energy costs and, thus, a more economical process overall. Moreover, the etch-activation solution, because of its composition, is less aggressive than the known etching solutions and is more stable than the known activation solutions. These characteristics allow for greater overall stability and permissible variance in the operation parameters, i.e., immersion times, temperatures, etc. As a result, the invention does not have to be maintained or closely monitored at high costs. More importantly, this stability results in good reproducibility and a low reject rate, which makes continuous rack occupation unnecessary.

In one embodiment of the invention, the conditioning of the plastic substrates with the etch-activation solution takes place over a period of about 1 to 10 minutes, preferably about 4 to 6 minutes. Since the invention avoids the conventional additional or multiple activation steps, a time savings is advantageously produced at this point in the process.

Beside the advantageous metal plating of complex plastic substrates, another advantage of the invention lies in the fact that currently existing metal plating facilities do not have to be torn down or reconstructed in order to use it.

Other process steps, especially rinse steps, can be included at the end of the conditioning step in accordance with the invention. Rinsing the conditioned plastic substrates several times at room temperature, preferably three times, is proposed.

At this point in the process, some of the treated plastic substrates have an advantageously prepared surface such that they can be directly electrolessly plated by, e.g., nickel or copper, without the typical second pretreatment step, the so called accelerator step. If an accelerator step is desired or necessary, the accelerator solution, contains at least one first reducing agent which is matched to the subsequent electroless process, and an additional reducing agent. The treatment of the plastic substrates in the second solution takes place from about 1 minute to 10 minutes, preferably 4 to 6 minutes, and at a temperature between 35° C. and 55° C., preferably between 40 and 50° C. At the end of this accelerator step an additional rinse step can be employed.

Plastic substrates pretreated with the etch-activation solution or prepared for electroless plating by the subsequent solutions are completely electrolessly plated in a third solution. This electroless plating solution contains at least one metal ion, e.g., copper or nickel ions; a reducing agent, e.g., sodium hypophosphite; a complexing agent, e.g., citric acid or ammonia; and a stabilizer, e.g., lead or bismuth. The plastic substrates remain in the plating solution between about 5 minutes to 15 minutes, preferably between about 8 minutes to 12 minutes. In addition, the third solution should have a pH value in the range from about 5 to 5.5, preferably about 5.2 to 5.4. The chemical reductive coating of the plastic substrates takes place at a temperature between about 60° C. and 75° C., preferably between about 65° C. and 70° C.

As an alternative to an electroless metal plating, a cheaper direct metal plating, e.g., nickel or copper plating, can take place after the accelerator solution. For this, one need only increase the palladium content of the etch-activation solution to about 100 ppm or more.

During the immersion of the plastic substrates in the respective solutions, the solution or of the plastic substrates are agitated, especially during the conditioning step. Agitation of the solution can be produced, for example, by bubbling air or by flooding the plastic substrate. Advantageously, it is ensured through the agitation of the solution or the plastic substrate that the solution can optimally act on the entire plastic surface. In this way, a functionally reliable and adherent metal plating is produced. In addition, it is proposed to filter the individual solutions during the individual process steps. This can take place in the solution or through a branched side stream outside the solution, e.g., through electrodialysis.

In addition, the solutions of this invention are to be protected. This is accomplished by making a solution available for simultaneous etching and activation of plastic substrates that includes one or more etching agents, an etching-active wetting agent, a mineral acid and an activator that contains noble metal ions.

Surprisingly, through the use of the solution in accordance with the invention, the plastics to be metal plated can be electroplated better, or electroplating in case of certain plastics, e.g., polyamide, is possible for the first time at all. The use of this solution for conditioning the plastic substrates is viewed as particularly advantageous. Specifically, at least one etching solution is combined with an activation solution in this solution, the so-called etch-activation solution. The use of this etch-activation solution brings about an extremely advantageous modification of the plastic surface so that immediately after a brief treatment time, pronounced voids, which are a basic prerequisite for firmly adhering metal layer, are formed and become simultaneously activated for metal plating. It is thus no longer necessary to condition the plastic surfaces at high cost and time with a separate processing step. In particular, only one process step, and not two or more conditioning steps, is necessary for the conditioning of large or complex work pieces, as well as plastics that are difficult to condition, e.g., polyamide, in contrast to the known methods.

The etch-activation solution of the invention advantageously contains, as the etching agent, about 10 mL to 30 mL of an organic acid such as formic acid, acetic acid, trifluoroacetic acid, or, preferably, acetic acid.

In addition, the etch-activation solution of the invention contains about 0.001 g/L to 10 g/L, preferably about 0.001 g/L to 1 g/L, of an etching-active wetting agent. A solution that contains perfluorinated or partially fluorinated wetting agents as the etching-active wetting agent is preferred, such as is available from Enthone Inc. USA under the trade designation UDIQUE BL 2030. The use of such wetting agents is advantageous, since they are stable in a highly acid solution.

Moreover, the etch-activation solution of the invention contains an ionic activator. The activator preferably contains noble metal ions, e.g., palladium ions. In particular, the use of about 10 mg/L to 1000 mg/L, preferably about 44 to 55 mg/L, divalent palladium ions in the etch-activation solution advantageously enables complete activation of the substrate surfaces, which in turn produces a functionally reliable and reproducible final metal plating. The use of such activators is advantageous, since they serve as metal plating seeds for most metals, especially copper and nickel.

### EXAMPLE 1

Plastic Substrate: Polyamide

Process Step 1: Conditioning (Pretreatment and Activation)

The plastic surface to be metal plated was introduced into an etch-activation solution containing a hydrochloric acid-containing polyamide etching agent and noble metal ions. An organic acid was used as polyamide etching agent and palladium chloride was used as noble metal ions.

Bath composition:

250 mL/L HCl (37%)

5 mL/L etching active wetting agent

25 mL/L acetic acid

50 ppm Pd2+

Reaction time: 4 min

Reaction temperature: 30° C.

Additional parameters:

Filtration

Agitation

Process Step 2: Rinse

The conditioned plastic substrates were rinsed at least one time, in the ideal case three times.

Process Step 3: Accelerator Solution

The plastic surface to be metal plated was optionally, in each case according to the results of treatment with the etch-activation solution, introduced into a second solution containing at least one first reducing agent matched to the subsequent solution for electroless metal plating and an additional reducing agent. Preferably sodium hypophosphite and dimethylaminoborane were used as reducing agents.

Bath composition:

20 g/L HCl sodium hypophosphite

1 g/L dimethylaminoborane

Reaction time: 4 min

Reaction temperature: 45° C.

Additional parameters:

Filtration

Process Step 4: Rinse

An additional rinse is carried out at this point, in each case as necessary.

Process Step 5: Chemical Nickel Coating

This coating solution contained nickel ions sodium hypophosphate as a reducing agent, citric acid and ammonium chloride as complexing agents, and lead ions as a stabilizer.

Bath composition:

4 g/L Ni²⁺ ions

3 g/L sodium hypophosphite

30 g/L citric acid

20 g/L ammonium chloride

1 ppm Pb²⁺ ions

Reaction time: 10 min

Reaction temperature: 65-68° C.

pH range: 5.2-5.4

Additional parameters:

Filtration

### EXAMPLE 2

Plastic Substrate: Polyamide

Process Step 1: Conditioning (Pretreatment and Activation)

The plastic surface to be metal plated was introduced into an etch-activation solution containing a hydrochloric acid-containing polyamide etching agent and noble metal ions. An organic acid was used as polyamide etching agent and palladium chloride was used as noble metal ions.

Bath composition:

250 mL/L HCl (37%)

5 mL/L etching active wetting agent

25 mL/L acetic acid

50 ppm Pd2+

Reaction time: 4 min

Reaction temperature: 30° C.

Additional parameters:

Filtration

Agitation

Process Step 2: Rinse

The conditioned plastic substrates were rinsed at least one time, in the ideal case three times.

Process Step 3: Accelerator Solution

The plastic surface to be metal plated was optionally, in each case according to the results of treatment with the etch-activation solution, introduced into a second solution containing at least one first reducing agent matched to the subsequent solution for electroless metal plating and an additional reducing agent. Preferably sodium hypophosphite and dimethylaminoborane were used as reducing agents.

Bath composition:

20 g/L HCl sodium hypophosphite

1 g/L dimethylaminoborane

Reaction time: 4 min

Reaction temperature: 45° C.

Additional parameters:

Filtration

Process Step 4: Chemical Nickel Coating

This coating solution contained nickel ions sodium hypophosphate as a reducing agent, citric acid and ammonium chloride as complexing agents, and lead ions as a stabilizer.

Bath composition:

4 g/L Ni²⁺ ions

3 g/L sodium hypophosphite

30 g/L citric acid

20 g/L ammonium chloride

1 ppm Pb²⁺ ions

Reaction time: 10 min

Reaction temperature: 65-68° C.

pH range: 5.2-5.4

Additional parameters:

Filtration

### EXAMPLE 3

Plastic Substrate: Polyamide

Process Step 1: Conditioning (Pretreatment and Activation)

The plastic surface to be metal plated was introduced into an etch-activation solution containing a hydrochloric acid-containing polyamide etching agent and noble metal ions. An organic acid was used as polyamide etching agent and palladium chloride was used as noble metal ions.

Bath composition:

250 mL/L HCl (37%)

5 mL/L etching active wetting agent

25 mL/L acetic acid

50 ppm Pd2+

Reaction time: 4 min

Reaction temperature: 30° C.

Additional parameters:

Filtration

Agitation

Process Step 2: Rinse

The conditioned plastic substrates were rinsed at least one time, in the ideal case three times.

Process step 3: Chemical Nickel Coating

This coating solution contained nickel ions sodium hypophosphate as a reducing agent, citric acid and ammonium chloride as complexing agents, and lead ions as a stabilizer.

Bath composition:

4 g/L Ni²⁺ ions

3 g/L sodium hypophosphite

30 g/L citric acid

20 g/L ammonium chloride

1 ppm Pb²⁺ ions

Reaction time: 10 min

Reaction temperature: 65-68° C.

pH range: 5.2-5.4

Additional parameters:

Filtration

It turned out that when using the etch-activation solution of the invention as in the Examples, the electroless deposition of nickel progresses more uniformly and the deposited nickel layers have higher specific conductivities than nickel layers that were produced analogously, but with individual etching and activation steps.

In addition, the electroplating conditions of the invention do not first have to be adjusted to the relevant plastic to be metal plated in order to bring about a functionally reliable and reproducible metal plating; rather, the quite varied plastics mentioned above can be metal plated with the method in accordance with the invention without costly process adjustment. Through the combination of etching and activation by means of the described etch-activation solution, the plastic surface is optimally prepared for metal plating.

The foregoing relates to a limited number of embodiments that have been provided for illustration purposes only. It is intended that the scope of invention is defined by the appended claims and there are modifications of the above embodiments that do not depart from the scope of the invention.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the invention are achieved and other advantageous results attained.

As various changes could be made in the above products and methods without departing from the scope of the invention, it is intended that all matter contained in the above description shall be interpreted as illustrative and not in a limiting sense.

What is claimed is:

1. A method for metal plating a plastic substrate comprising:
etching and activating the plastic substrate by exposing the substrate to an etch-activation solution comprising a mineral acid-containing etching agent and an ionic activator, and
plating metal onto the substrate by chemically reductive metal deposition or electrolytic metal deposition in a plating solution.

2. The method of claim 1 wherein the plastic substrate is exposed to an accelerator solution before plating the metal onto the substrate.

3. The method of claim 1, wherein the plastic substrate is a polyamide substrate.

4. The method of claim 1, wherein the etch-activation solution comprises an etching agent, an etching-active wetting agent, a mineral acid, and an activator containing noble metal ions.

5. The method of claim 1, wherein the etch-activation solution is maintained at a temperature between about 20° C. and about 90° C.

6. The method of claim 1, wherein the etch-activation solution is maintained at a temperature between about 30° C. and about 35° C.

7. The method of claim 1, wherein the plastic substrate is exposed to the etch-activation solution for between about 1 minute to about 10 minutes.

8. The method of claim 1, wherein the plastic substrate is exposed to the etch-activation solution for between about 4 minutes to about 6 minutes.

9. The method of claim 2, wherein the plastic substrate is treated with the accelerator solution for between about 1 minute to about 10 minutes.

10. The method of claim 2, wherein the plastic substrate is treated with the accelerator solution for between about 4 minutes to about 6 minutes.

11. The method of claim 2, wherein the plastic substrate is treated with the accelerator solution at a temperature between about 35° C. and about 55° C.

12. The method of claim 2, wherein the plastic substrate is treated with the accelerator solution at a temperature between about 40° C. and about 50° C.

13. The method of claim 2, wherein the accelerator solution comprises one first reducing agent matched to the subsequent electroless process and an additional reducing agent.

14. The method of claim 1, wherein the plastic substrate is exposed to the plating solution for about 5 minutes to about 15 minutes.

15. The method of claim 1, wherein the plastic substrate is coated by chemical reductive means with the plating solution for about 8 minutes to about 12 minutes.

16. The method of claim 1, wherein the plating solution comprises one metal ion, a reducing agent, a complexing agent and a stabilizer.

17. The method of claim 1, wherein the solutions, the plastic substrate in the solutions, or both are agitated.

18. The method of claim 1, wherein the solutions are filtered.

19. A solution for simultaneous etching and activation of plastic substrates comprising an etching agent, an etching-active wetting agent, a mineral acid, and an activator containing noble metal ions.

20. The solution of claim 19, wherein the etching agent is an organic acid.

21. The solution of claim 20, wherein the organic acid is present in a concentration between about 0 g/L to about 50 g/L.

22. The solution of claim 20, wherein the organic acid is selected from the group consisting of formic acid, acetic acid, trifluoroacetic acid, or any combination thereof.

23. The solution of claim 19, wherein the etching-active wetting agent is present in a concentration between about 0.001 g/L to about 10 g/L.

24. The solution of claim 19, wherein the etching-active wetting agent is present in a concentration between about 0.01 g/L to about 1 g/L.

25. The solution of claim 19, wherein the etching-active wetting agent is selected from the group consisting of perfluorinated wetting agents or partially fluorinated wetting agents.

26. The solution of claim 19, wherein the solution further comprises about 200 mL/L to about 300 mL/L of a 37% hydrochloric acid.

27. The solution of claim 19, wherein the solution further comprises about 225 mL/L to about 275 mL/L of a 37% hydrochloric acid.

28. The solution of claim 19, wherein the ionic activator comprises about 10 mg/L to about 1000 mg/L divalent palladium ions.

29. The solution of claim 19, wherein the ionic activator comprises about 45 mg/L to about 55 mg/L divalent palladium ions.
